(19) United States
(12) Patent Application Publication
(10) Pub. No.: US 2026/0274652 A1
(43) Pub. Date: Sep. 17, 2026

(54) Sound Producing Device and Sound Producing Package

(71) Applicant: xMEMS Labs, Inc., Santa Clara, CA (US)

(72) Inventors: Chih-Yang Tsai, Hsinchu City (TW); Eldwin Jiaqiang Ng, Sunnyvale, CA (US); Wen-Chien Chen, New Taipei City (TW); Chun-Chieh Chang, Taoyuan City (TW); Chiung C. Lo, San Jose, CA (US); Michael David Housholder, San Jose, CA (US); JengYaw Jiang, Saratoga, CA (US)

(73) Assignee: xMEMS Labs, Inc., Santa Clara, CA (US)

(21) Appl. No.: 19/562,725

(22) Filed: Mar. 10, 2026

Related U.S. Application Data
(60) Provisional application No. 63/989,194, filed on Feb. 23, 2026.
(60) Provisional application No. 63/772,367, filed on Mar. 14, 2025.

(51) Int. Cl. B81B 7/02; H04R 1/28

(52) U.S. Cl. CPC B81B 7/02; H04R 1/2811; B81B 2201/0257; B81B 2207/012; B81B 2207/07; H04R 2201/003

(57) ABSTRACT

A sound producing device comprises a first substrate, wherein a slot is formed in the first substrate; an air pulse generating (APG) device, configured to generate a plurality of air pulses at an ultrasonic operating frequency, disposed on a second substrate, wherein a vent is formed within the second substrate; and a driving circuit, configured to drive the APG device, disposed on the first substrate.

### CROSS REFERENCE TO RELATED APPLICATIONS

This application claims the benefit of U.S. Provisional Application No. 63/772,367, filed on Mar. 14th, 2025. Further, this application claims the benefit of U.S. Provisional Application No. 63/989,194, filed on Feb. 23rd, 2026. The contents of these applications are incorporated herein by reference.

### BACKGROUND OF THE INVENTION

### 1. Field of Invention

The present application relates to a sound producing device and a sound producing package, and more particularly, to a sound producing device and a sound producing package with compact size and improved acoustic performance.

### 2. Description of the Prior Art

Unless otherwise indicated herein, the approaches described in this section are not prior art to the claims in this application and are not admitted as prior art by inclusion in this section.

Speaker driver and back enclosure are two major design challenges in the speaker industry. It is difficult for a conventional speaker to cover an entire audio frequency band, e.g., from 20 Hz to 20 KHz. To produce high fidelity sound with high enough sound pressure level (SPL), both the radiating/moving surface and volume/size of back enclosure for the conventional speaker are required to be sufficiently large.

Air-pulse generating (APG) device has been disclosed to overcome the design challenges faced by conventional speakers. However, how to design a compact module or package with good acoustic performance is a significant objective in the field.

### SUMMARY OF THE INVENTION

It is therefore a primary objective of the present application to provide a sound producing device and a sound producing package, to improve over the prior art.

An embodiment of the present application provides a sound producing device. The sound producing device comprises a first substrate, wherein a slot is formed in the first substrate; an air pulse generating (APG) device, configured to generate a plurality of air pulses at an ultrasonic operating frequency, disposed on a second substrate, wherein a vent is formed within the second substrate; and a driving circuit, configured to drive the APG device, disposed on the first substrate.

Another embodiment of the present application provides a sound producing package. The sound producing package comprises an air pulse generating (APG) device, configured to generate a plurality of air pulses at an ultrasonic operating frequency, disposed on a substrate, wherein a vent is formed on the substrate; a driving circuit, configured to drive the APG device; and a covering structure; wherein the APG device and the driving circuit are disposed on a first side of the substrate; wherein the covering structure covers the APG device and the driving circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a sound producing device according to an embodiment of the present application.

FIG. 2 is a schematic diagram of a sound producing device according to an embodiment of the present application.

FIG. 3 is a schematic diagram of an air pulse generating device according to an embodiment of the present application.

FIG. 4 is a schematic diagram of an air pulse generating device according to an embodiment of the present application.

FIG. 5 is a schematic diagram of a sound producing package according to an embodiment of the present application.

FIG. 6 is a schematic diagram of a sound producing package according to an embodiment of the present application.

FIG. 7 is a schematic diagram of a sound producing package according to an embodiment of the present application.

FIG. 8 is a schematic diagram of a sound producing package according to an embodiment of the present application.

FIG. 9 is a schematic diagram of a sound producing device according to an embodiment of the present application.

FIG. 10 is a schematic diagram of an air pulse generating device according to an embodiment of the present application.

FIG. 11 illustrates a schematic diagram of a frequency response of an air pulse generating device with resonance chamber according to an embodiment of the present application.

### DETAILED DESCRIPTION

The technical features described in the embodiments of the present invention may be mixed or combined in various ways as long as there are no conflicts between them.

Content of US No. 11,943,585, No. 12,261,567, No. 12,107,546, No. 12,413,900 and Application No. 19/424,094 is incorporated herein by reference.

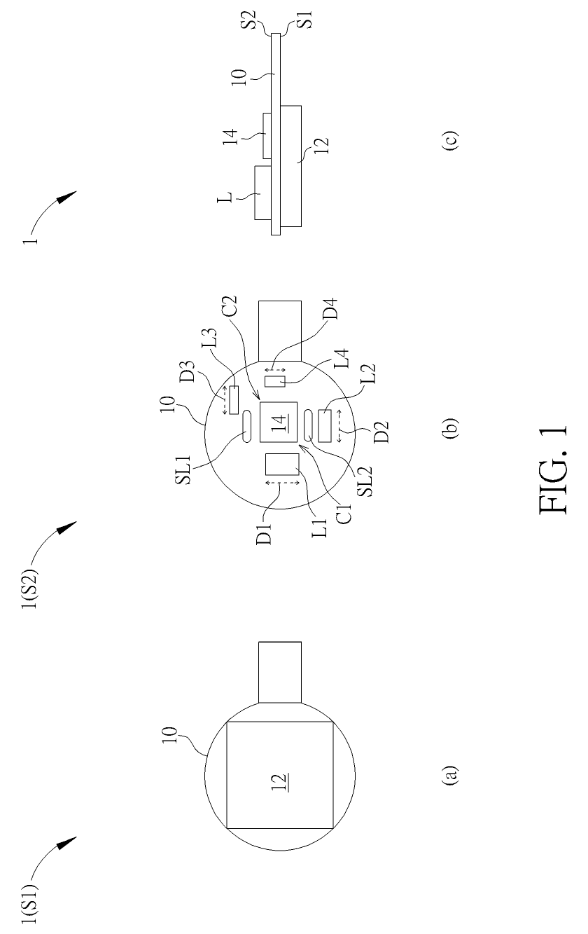

FIG. 1 is a schematic diagram of a sound producing device 1 according to an embodiment of the present application. Specifically, FIGS. 1(a) /1(b) illustrates a view of a first/second side of the sound producing device 1, and FIG. 1(c) illustrates a cross-sectional view of the sound producing device 1. The sound producing device 1 comprises a first substrate 10, an air pulse generating (APG) device 12, a driving circuit 14. The first substrate 10 may be a printed circuit board (PCB). The APG device 12 is configured to generate a plurality of air pulses at an ultrasonic operating frequency. The driving circuit is configured to drive the APG device 12.

Details of the APG device may be referred to US Patent No. 11,943,585, and details of the driving circuit may be referred to US Patent No. 12,261,567 and No. 12,107,546, which are not narrated herein for brevity.

Disposing the APG device 12 on the first substrate 10 may involve a surface mount technology (SMT) process. The driving circuit 14 may be formed as a wafer level chip scale package (WLCSP).

In the embodiment shown in FIG. 1, in order to fulfill practical requirement (e.g., to be able to be disposed within wearable sound device such as earbud), the first substrate 10 may comprise a truncated circular periphery or even a circular periphery, which is not limited thereto.

In the embodiment shown in FIG. 1, in order to reduce an entirely occupied area of the sound producing device 1, the APG device 12 is disposed on a first side S1 of the first substrate 10, and the driving circuit 14 is disposed on a second side S2 of the first substrate 10.

Furthermore, to achieve better acoustic performance, a first slot SL1 and a second slot SL2 are formed on the first substrate 10. In the embodiment shown in FIG. 1, in order to achieve better spatial utilization efficiency, the driving circuit 14 is disposed between the first slot SL1 and the second slot SL2 on the second side S2 of the first substrate 10.

Furthermore, the sound producing device 1 may comprise (electric) inductors L1-L4. The driving circuit 14 may cooperate with the inductors L1-L4 to generate driving signals to drive the APG device 12. In the embodiment shown in FIG. 1, the inductors L1, L2 may be disposed adjacent to a first corner C1 of the driving circuit 14, and the inductors L3, L4 may be disposed adjacent to a second corner C2 of the driving circuit 14, where the second corner C2 may be diagonally opposite to the first corner C1. Note that, in order to reduce occupied area of the sound producing device 1, the inductors L1, L2 may be placed such that a magnetic direction D1 of the inductor L1 and a magnetic direction D2 of the inductor L2 are perpendicular to each other. Similarly, the inductors L3, L4 may be placed such that a magnetic direction D3 of the inductor L3 and a magnetic direction D4 of the inductor L4 are perpendicular to each other. The inductor L shown in FIG. 1(c) may represent one of the inductors L1-L4.

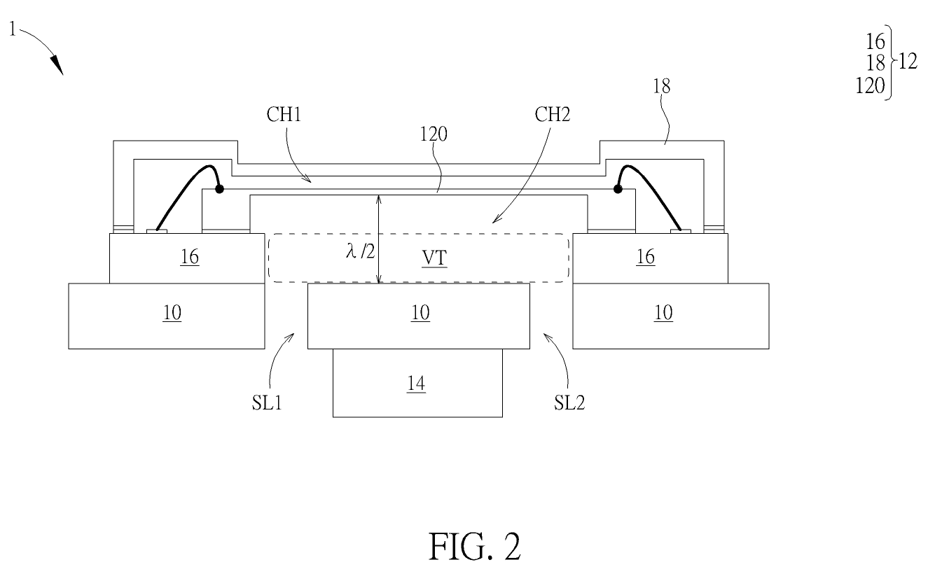

FIG. 2 is a schematic diagram of a cross-sectional view of the sound producing device 1 according to an embodiment of the present application. In an embodiment (or in a perspective), the APG device 12 comprises a film structure 120, a covering structure 18 and a second substrate 16. In an embodiment, the covering structure 18 may be a metal lid. The second substrate 16 may be, for example, an LGA (Land Grid Array) substrate, but not limited thereto. A vent VT is formed within the second substrate 16.

Note that, a first chamber CH1 is formed between the film structure 120 and the covering structure 18, and a second chamber CH2 is formed between the film structure 120 and the first substrate 10. In order to enhance acoustic performance (e.g., sound pressure level (SPL)), distance between the film structure 120 and the covering structure 18 may be designed such that a Helmholtz resonance is formed within the first chamber CH1. In addition, distance between the film structure 120 and the first substrate 10 may be designed such that a standing wave resonance is formed within the second chamber CH2. For example, a distance between the film structure 120 and the first substrate 10 may be designed as a half-wavelength λ/2 corresponding to the ultrasonic operating frequency of the APG device 12.

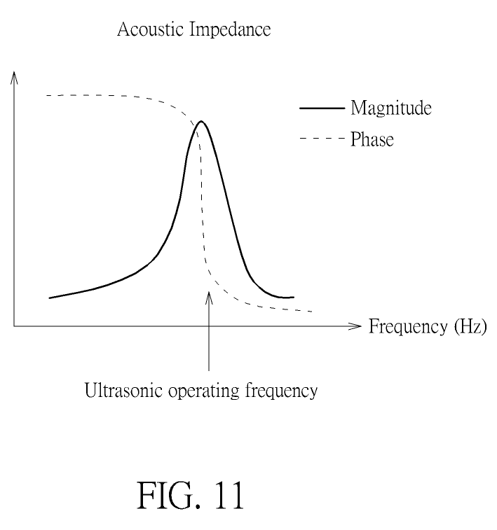

Specifically, the APG device (e.g., 12) disclosed in No. 11,943,585 produces airflow pulses, and resonance chamber (either Helmholtz resonance in resonance chamber CH1 or standing wave resonance in resonance chamber CH2) may form a peak on frequency response of acoustic impedance at the ultrasonic operating frequency. Therefore, acoustic pressure (or SPL) would be increased. FIG. 11 illustrates a schematic diagram of a frequency response of an APG device having (Helmholtz or standing wave) resonance chamber. As can be seen from FIG. 11, the APG device having (Helmholtz or standing wave) resonance chamber has a peak on frequency response of acoustic impedance at the ultrasonic operating frequency. Details of resonance chamber and peak of acoustic impedance may be referred to US patent No. 12,413,900, which is not narrated herein for brevity.

In FIG. 2, outlet(s) formed on the covering structure 18 and slit(s) formed on the film structure 120 are omitted for brevity.

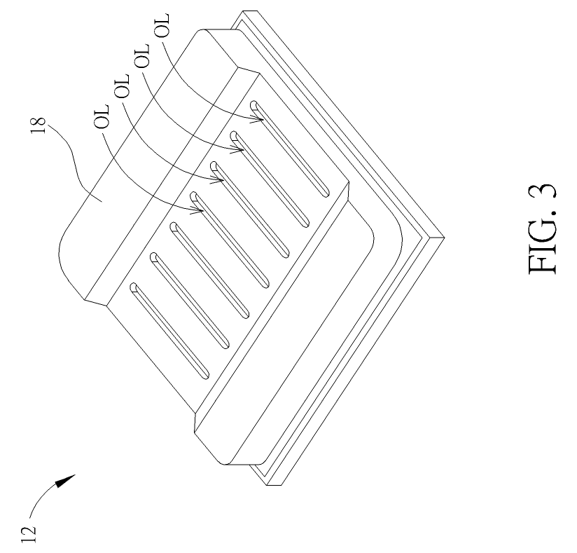

FIG. 3 is a schematic diagram of an appearance of the APG device 12 according to an embodiment of the present application. The APG device 12 may be itself a sound producing package, which comprises the covering structure 18. To achieve better acoustic performance, a plurality of outlets OL are formed on the covering structure 18, and the plurality of outlets OL have an elongated shape and are arranged in parallel.

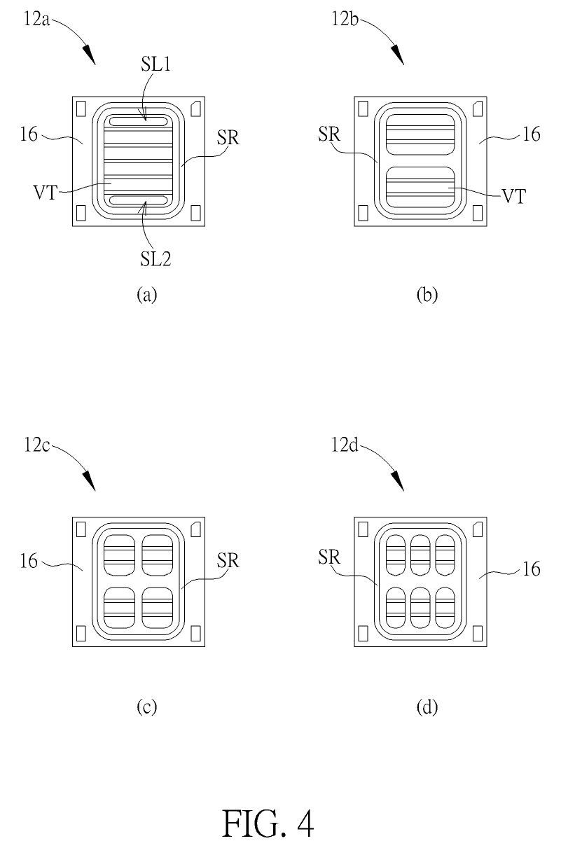

FIG. 4 is a schematic diagram of a bottom view of the APG device (e.g., 12) according to an embodiment of the present application. Specifically, FIGS. 4(a)-4(d) illustrates bottom view of APG devices 12a-12d according to embodiments of the present application. In FIGS. 4(a)/ 4(b) /4(d) , one/two/four/six vent(s) may be formed in the second substrate 16. Number of vents formed in the second substrate 16 may be designed according to practical requirements.

In FIG. 4(a), the slot SL1/SL2 is illustrated. As can be seen from FIG. 4(a), a projection of the vent VT onto the first substrate 10 overlaps with the slot SL1/SL2. Hence, the (back) chamber CH2 would comprise/connect the vent VT and the slot SL1/SL2. Design of the vent VT and the slot SL1/SL2 would affect acoustic performance.

For example, a thicker first substrate may have a lower Helmholtz frequency (representing or corresponding to a peak of acoustic impedance) and may slightly degrade audible band performance. That is, a thin first substrate may move the Helmholtz frequency toward higher frequency beyond audible band, which would improve acoustic performance. According to simulation, a thickness of the first substrate (e.g., PCB) is suggested to be 0.4±0.1 millimeter (mm). In general, to achieve better acoustic performance, the thickness of the first substrate (e.g., PCB) may be no greater than 0.5 mm, which is not limited thereto.

Furthermore, the APG device (e.g., 12a-12d) comprises a seal ring SR surrounding and enclosing the vent(s) VT. The seal ring SR may be made of conductive adhesive material, e.g., solder. The seal ring SR is configured to seal air gap between the first substrate (e.g., PCB) and the second substrate (e.g., LGA) to prevent air leakage away from the chamber CH2, so as to improve acoustic performance.

Note that, in the sound producing device 1, the APG device 12 and the driving circuit 14 may themselves be (semiconductor) package, and the sound producing device 1 may be regarded as a sound producing module, comprising two (semiconductor) packages: one for air-pulse generating and one for driving.

Note that, component of air-pulse generating and component of driving may be integrated into a (sound producing) package.

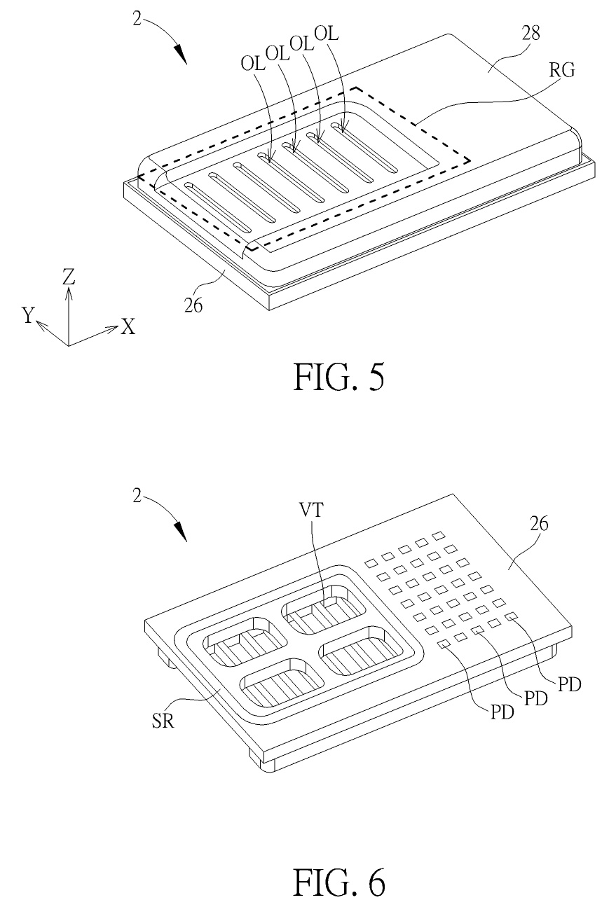

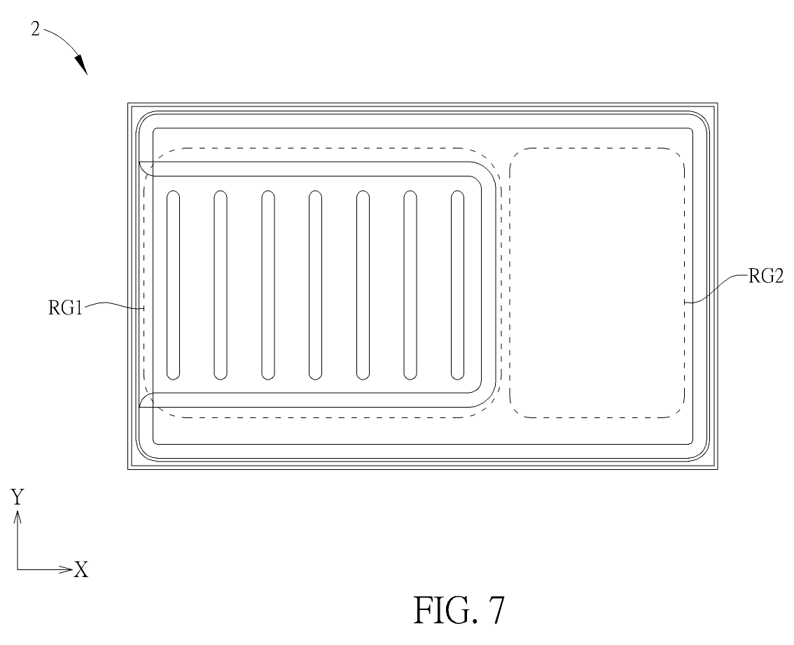

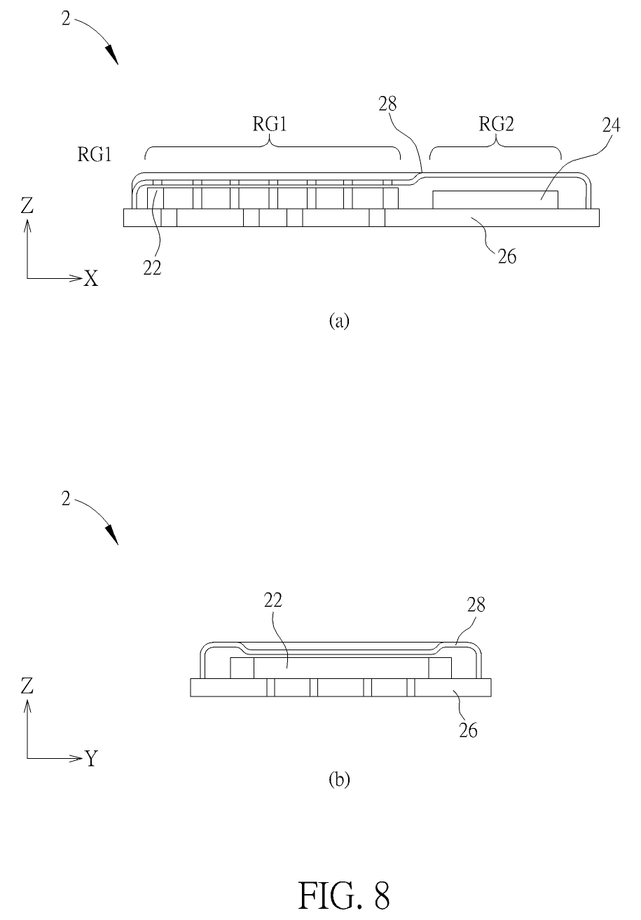

FIG. 5 is a schematic diagram of a top-side appearance of a sound producing package 2 according to an embodiment of the present application. FIG. 6 is a schematic diagram of a bottom-side appearance of the sound producing package 2 according to an embodiment of the present application. FIG. 7 is a schematic diagram of a top view of the sound producing package 2 according to an embodiment of the present application. FIG. 8 is a schematic diagram of a cross-sectional view of the sound producing package 2 according to an embodiment of the present application.

The sound producing package 2 comprises an APG device 22, a driving circuit 24 and a covering structure 28. The APG device 22 may be a MEMS (Micro-Electro-Mechanical Systems) fabricated or semiconductor (e.g., silicon) fabricated device comprising supporting structure and film structure. The driving circuit 24 may be in a form of an integrated circuit (IC). The APG device 22 and the driving circuit 24 may be disposed on a (same) side of a substrate 26. The substrate 26 may be, for example, an LGA substrate, but not limited thereto. The covering structure 28 covers the APG device 22 and the driving circuit 24. The sound producing package 2 may be viewed as a multi-chip package (MCP).

Similar to the covering structure 18, a plurality of outlets OL are formed on the covering structure 28, and the outlets OL have an elongated shape and are arranged in parallel. It can be viewed that the covering structure 28 comprises a first region RG1 corresponding to the APG device 22 and a second region RG2 corresponding to the driving circuit 24. The outlets OL lie in the first region RG1.

In addition, the sound producing package 2 comprises a seal ring SR and a plurality of pads PD formed on the substrate 26. The seal ring SR surrounds and encloses vent(s) VT formed in the substrate 26. The plurality of pads PD provide signal transmission paths for the driving circuit 24. The seal ring SR and the vent(s) VT are corresponding to the first region RG1 and the plurality of pads PD are corresponding to the second region RG2.

In addition, a recess region RG may be formed on the covering structure 28, overlapping with the first region RG1 that corresponds to the APG device and covering the APG device 22 underneath. The recess region RG may be configured to form/facilitate the Helmholtz resonance, so as to enhance acoustic performance.

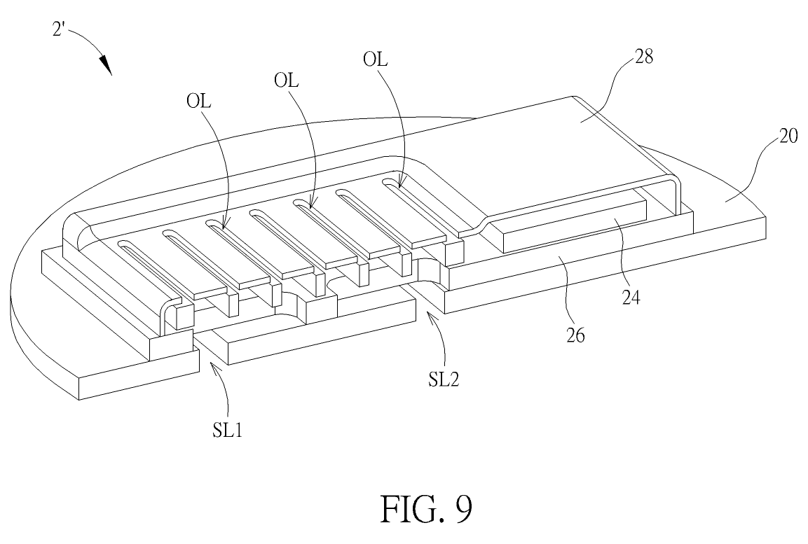

FIG. 9 is a schematic diagram (of a cross-sectional view) of a sound producing device 2’ according to an embodiment of the present application. The sound producing device 2’ may be viewed as disposing the sound producing package 2 on a first substrate (e.g., PCB) 20.

Similarly, the first substrate 20 may comprise a truncated circular periphery or a circular periphery, which is not limited thereto

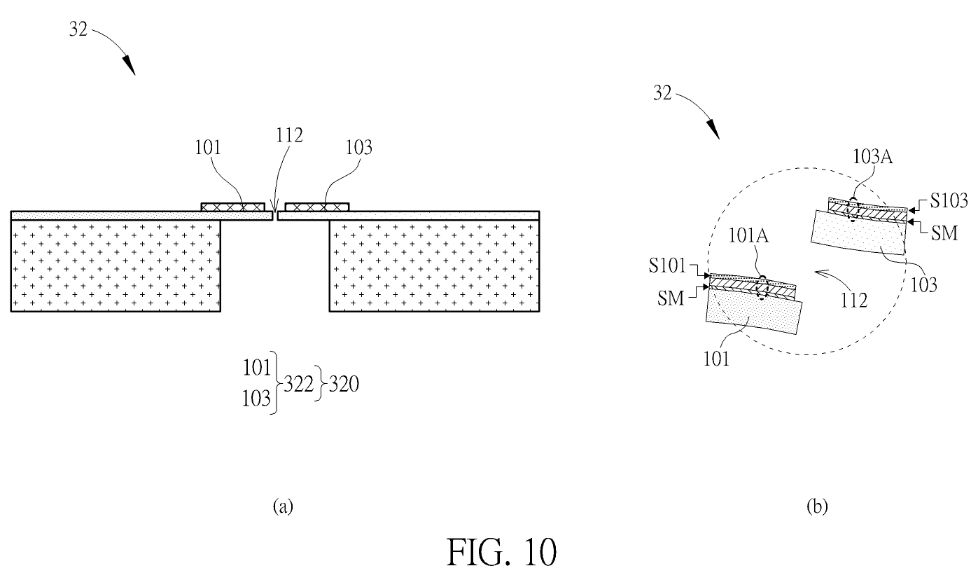

FIG. 10 is a schematic diagram of an air pulse generating device 32 disclosed in No. 11,943,585. The APG device 32 comprises a film structure 320, and the film structure 320 comprises a flap pair 322. The flap pair 322 comprises flap 101 and 103. The APG device 32 also comprises an actuator 101A disposed on the flap 101 and an actuator 103A disposed on the flap 103. The actuator 101A/103A is driven by a demodulation/valve driving signal S101/S103 and a modulation/pressure driving signal SM, to produce a plurality of air pulses at an ultrasonic pulse rate as the ultrasonic operating frequency. The actuator 101A/103A comprises a top electrode and a bottom electrode. The two electrodes receive the demodulation/valve driving signal and the modulation/pressure driving signal. In the embodiment shown in FIG. 10, the top electrode receives the demodulation/valve driving signal S101/S103 and the bottom electrode receives the modulation/pressure driving signal SM, but not limited thereto.

The modulation/pressure driving signal SM drives the flap pair to perform a common mode movement. The demodulation/valve driving signals S101 and S103 drive the flap pair to perform a differential mode movement. Suppose U_{z,101} and U_{z,103} represents displacement (in Z/vertical direction) of the flaps 101 and 103, respectively. Then the common mode movement may refer to a movement component of the flap pair which is (U_{z,101} + U_{z,103})/2, and the differential mode movement may refer to a movement component of the flap pair which is |U_{z,101} - U_{z,103}|/2.

A slit 112 is formed between the flaps 101 and 103. When the flap pair performs the differential mode movement (sometimes abbreviated as differential movement) such that ΔU_{z} = |U_{z,101} - U_{z,103}| is greater than a thickness of the flap, an opening (also denoted as 112) is formed. In one perspective, the differential movement of flaps 101 and 103 forms a virtual valve, also denoted as 112. When ΔU_{z} is small (smaller than the thickness of the flap) and/or an acoustic impedance/resistance is large so that airflow through the virtual valve 112 is negligible, the virtual valve 112 can be viewed as the slit 112, as shown in FIG. 10(a). When ΔU_{z} is large (larger than the thickness of the flap) and/or an acoustic impedance/resistance is small so that airflow through the virtual valve 112 is significant, the virtual valve 112 can be viewed as the opening 112, as shown in FIG. 10(b).

The waveform of the modulation/pressure driving signal SM can be viewed as a (generalized) double sideband with suppressed carrier (DSB-SC), where a definition of “generalized DSB-SC” may be referred to US Patent No. 12,107,546, which is not narrated herein for brevity. The waveform of the demodulation/valve driving signal S101/S103 can be viewed as a square/rectangular wave (similar to clock signal(s)), but not limited thereto. Note that, the phase relationship between the modulation/pressure driving signal and the demodulation/valve driving signal is adaptable.

The demodulation/valve driving signals S101 and S103 may or may not be biased at the same level. When the demodulation/valve driving signals S101 and S103 are biased at the same level, the flap pair may perform a symmetric differential movement without initial deflection. On the other hand, when the demodulation/valve driving signals S101 and S103 are biased at different levels, the flap pair would perform an asymmetric differential movement with asymmetric initial deflection. Details of initial deflection may be referred to US Application No. 19/424,094, which is not detailed herein for brevity.

In other words, the flap pair 322 performs the common mode movement at a pressure variant frequency and the ultrasonic operating frequency is the pressure variant frequency. Meanwhile, the flap pair 322 performs the differential mode movement to form the virtual valve 112 at an opening frequency and the ultrasonic operating frequency is the opening frequency.

In conclusion, the present application provides a compact module and/or package (e.g., multi-chip package (MCP)) featuring a PCB with a truncated circular periphery for optimized space utilization. The integration of a MEMS device and a driving circuit, along with the strategic placement of passive components (L1, L2) adjacent to a first corner of the MEMS device, ensures an efficient layout within the module. Furthermore, the seal ring effectively surrounds and encloses the vent formed in the substrate to maintain acoustic integrity. Combined with parallel elongated outlets on the covering structure as well as the resonance chambers, the package achieves superior acoustic performance and reliability for micro-speaker applications.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A sound producing device, comprising:
a first substrate, wherein a slot is formed in the first substrate;
an air pulse generating (APG) device, configured to generate a plurality of air pulses at an ultrasonic operating frequency, disposed on a second substrate, wherein a vent is formed within the second substrate; and
a driving circuit, configured to drive the APG device, disposed on the first substrate.

2. The sound producing device of claim 1,
wherein the APG device is disposed on a first side of the first substrate, and the driving circuit is disposed on a second side of the first substrate.

3. The sound producing device of claim 1,
wherein a first slot and a second slot are formed on the first substrate.

4. The sound producing device of claim 3,
wherein the APG device covers the first slot and the second slot on a first side of the first substrate;
wherein the driving circuit is disposed between the first slot and the second slot on a second side of the first substrate.

5. The sound producing device of claim 1, comprising:
a covering structure;
wherein a plurality of outlets are formed on the covering structure.

6. The sound producing device of claim 5,
wherein the plurality of outlets have an elongated shape and are arranged in parallel.

7. The sound producing device of claim 1, comprising a seal ring surrounding and enclosing the vent.

8. The sound producing device of claim 1,
wherein a projection of the vent onto the first substrate overlaps with the slot.

9. The sound producing device of claim 1,
wherein the APG device comprises a film structure.

10. The sound producing device of claim 9,
wherein a Helmholtz resonance is formed within a first chamber between the film structure and a covering structure of the APG device;
wherein the APG device has a peak on a frequency response of an acoustic impedance at the ultrasonic operating frequency.

11. The sound producing device of claim 9,
wherein a standing wave resonance is formed within a second chamber between the film structure and the first substrate;
wherein the APG device has a peak on a frequency response of an acoustic impedance at the ultrasonic operating frequency.

12. The sound producing device of claim 9,
wherein a distance between the film structure and the first substrate is a half-wavelength corresponding to the ultrasonic operating frequency of the APG device.

13. The sound producing device of claim 9,
wherein the film structure comprises a flap pair;
wherein the flap pair performs a common mode movement at a pressure variant frequency;
wherein the ultrasonic operating frequency is the pressure variant frequency.

14. The sound producing device of claim 13,
wherein the flap pair performs a differential mode movement to form a virtual valve at an opening frequency;
wherein the ultrasonic operating frequency is the opening frequency.

15. The sound producing device of claim 1, comprising:
a first inductor and a second inductor;
wherein the first inductor and the second inductor are disposed adjacent to a first corner of the driving circuit.

16. The sound producing device of claim 15,
wherein a first magnetic direction of the first inductor and a second magnetic direction of the second inductor are perpendicular to each other.

17. The sound producing device of claim 15, comprising:
a third inductor and a fourth inductor;
wherein the third inductor and the fourth inductor are disposed adjacent to a second corner of the driving circuit;
wherein the second corner is diagonally opposite to the first corner.

18. The sound producing device of claim 17,
wherein a third magnetic direction of the third inductor and a fourth magnetic direction of the fourth inductor are perpendicular to each other.

19. The sound producing device of claim 1,
wherein the first substrate comprises a truncated circular periphery or a circular periphery.

20. The sound producing device of claim 1,
wherein a thickness of the first substrate is no greater than 0.5 millimeter.

21. The sound producing device of claim 1,
wherein disposing the APG device on the first substrate involves a surface mount technology (SMT) process.

22. The sound producing device of claim 1,
wherein the driving circuit is formed as a wafer level chip scale package (WLCSP).

23. A sound producing package, comprising:
an air pulse generating (APG) device, configured to generate a plurality of air pulses at an ultrasonic operating frequency, disposed on a substrate, wherein a vent is formed on the substrate;
a driving circuit, configured to drive the APG device; and
a covering structure;
wherein the APG device and the driving circuit are disposed on a first side of the substrate;
wherein the covering structure covers the APG device and the driving circuit.

24. The sound producing package of claim 23,
wherein a plurality of outlets are formed on the covering structure;
wherein the plurality of outlets have an elongated shape and are arranged in parallel.

25. The sound producing package of claim 23,
wherein the covering structure comprises a first region corresponding to the APG device and a second region corresponding to the driving circuit;
wherein the plurality of outlets are arranged within the first region.

26. The sound producing package of claim 23,
wherein the APG device comprises a film structure;
wherein a Helmholtz resonance is formed within a chamber between the film structure and the covering structure;
wherein the APG device has a peak on a frequency response of an acoustic impedance at the ultrasonic operating frequency.

27. The sound producing package of claim 23, comprising a seal ring surrounding the vent.

28. The sound producing package of claim 23, comprising:
a plurality of pads formed on the substrate, configured to provide signal paths for the driving circuit.

29. The sound producing package of claim 23,
wherein a recess region is formed on the covering structure.
